(19) United States
(12) Patent Application Publication
(10) Pub. No.: US 2023/0292541 A1
(43) Pub. Date: Sep. 14, 2023

(54) DISPLAY DEVICE

(71) Applicant: SHARP KABUSHIKI KAISHA, Sakai-City, Osaka (JP)

(72) Inventors: SHINICHI HANDA, Sakai City, Osaka (JP); YUSUKE SAKAKIBARA, Sakai City, Osaka (JP)

(21) Appl. No.: 18/011,087

(22) PCT Filed: Jun. 22, 2020
(86) PCT No.: PCT/JP2020/024320

§ 371 Date: Dec. 16, 2022

(51) Int. Cl. H10K 50/16; H10K 50/15; H10K 50/115

(52) U.S. Cl. CPC H10K 50/16; H10K 50/15; H10K 50/115; H10K 2102/331

(57) ABSTRACT

An electron transport layer of a display device includes a mixture in which a first material and a second material are mixed, an electron affinity of a first light-emitting layer is equal to or smaller than an electron affinity of the first material, an electron affinity of the second material is smaller than the electron affinity of the first material, and an electron affinity of a second light-emitting layer is equal to or smaller than the electron affinity of the second material.

### TECHNICAL FIELD

The present invention relates to a display device including pixels of a plurality of colors on one substrate, each pixel including an anode electrode, a hole transport layer (HTL), a light-emitting layer, an electron transport layer (ETL), and a cathode electrode.

### BACKGROUND ART

There is known a display device including a red pixel, a green pixel, and a blue pixel on one substrate, each pixel including an anode electrode, a hole transport layer, a light-emitting layer, an electron transport layer, and a cathode electrode (PTL 1). The electron transport layer of the display device includes an identical material for the red pixel, the green pixel, and the blue pixel.

### CITATION LIST

### Patent Literature

PTL 1: JP 2010-244885 A (published on Oct. 28, 2010)

### SUMMARY OF INVENTION

### Technical Problem

However, when emitted light is of different colors, the electron affinities of the light-emitting layers are different, and thus, there is a problem that when the materials of the electron transport layers of the red pixel, the green pixel, and the blue pixel are commonalized with one material having a single electron affinity, enhancing a luminous efficiency for all three colors of the red pixel, the green pixel, and the blue pixel is not possible.

When electron transport layers suitable for light-emitting layers of respective colors are separately formed to achieve a high luminous efficiency for all the three color pixels, a process of forming the electron transport layers increases. In addition, when a process of forming the electron transport layer of a certain color is a process different from a process of forming the electron transport layer of another color, film thicknesses of the electron transport layers may be greatly different between adjacent pixels of different colors, resulting in a problem where color unevenness is likely to be generated on an image or a video displayed on the display device.

### Solution to Problem

A display device according to the present invention includes a first light-emitting layer configured to emit light of a first wavelength along a first direction, a second light-emitting layer arranged with respect to the first light-emitting layer along a second direction intersecting the first direction and configured to emit light of a second wavelength different from the first wavelength along the first direction, an electron transport layer common to the first light-emitting layer and the second light-emitting layer and configured to supply electrons to the first light-emitting layer and the second light-emitting layer, and a cathode electrode configured to supply the electrons to the electron transport layer, in which the electron transport layer includes a mixture in which a first material and a second material are mixed, an electron affinity of the first light-emitting layer is equal to or smaller than an electron affinity of the first material, an electron affinity of the second material is smaller than the electron affinity of the first material, and an electron affinity of the second light-emitting layer is equal to or smaller than the electron affinity of the second material.

### Advantageous Effects of Invention

According to an aspect of the present invention, the luminous efficiency can be enhanced for a plurality of pixels of different colors while forming a charge transport layer using a material common to a plurality of light-emitting layers of different color.

### BRIEF DESCRIPTION OF DRAWINGS

FIG. 1 is a cross-sectional view of a display device according to a first embodiment.

FIG. 2 is a diagram illustrating a flow of injecting electrons into a light-emitting layer provided in the display device.

FIG. 3 is a diagram for describing injection of electrons from an electron transport layer to the light-emitting layer provided in the display device.

FIG. 4 is a circuit diagram of an equivalent circuit related to injection of electrons from the electron transport layer to the light-emitting layer.

FIG. 5 is a diagram for describing an injection barrier of electrons from the electron transport layer to the light-emitting layer.

FIG. 6 is a graph showing a relationship between materials of the electron transport layer and energies relative to a vacuum level.

FIG. 7 is a diagram for describing an image of injecting electrons from the electron transport layer into the light-emitting layer.

FIG. 8 is a graph showing a relationship among a particle radius of a material of the electron transport layer, a bandgap, and an electron affinity.

FIG. 9 is a graph showing a relationship between a composition of a material of the electron transport layer and an electron affinity.

FIG. 10 is a cross-sectional view of a display device according to a modified example of the first embodiment.

FIG. 11 is a cross-sectional view of a display device according to a second embodiment.

FIG. 12 is a diagram for describing an electron level of the light-emitting layer provided in the display device according to the first embodiment.

FIG. 13 is a diagram for describing an electron level of a light-emitting layer provided in the display device according to the second embodiment.

FIG. 14 is a diagram for describing an injection barrier of a positive hole from a hole transport layer to the light-emitting layer provided in the display device.

FIG. 15 is a cross-sectional view of a display device according to a modified example of the second embodiment.

### DESCRIPTION OF EMBODIMENTS

### First Embodiment

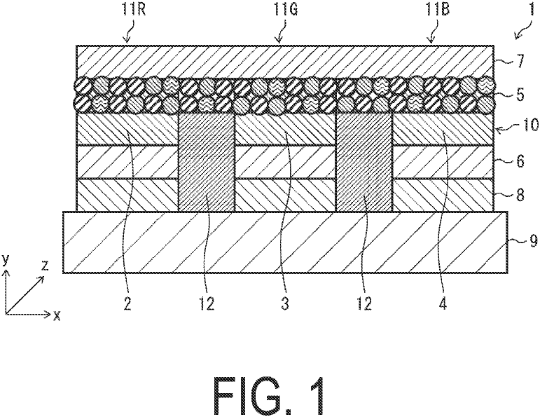

FIG. 1 is a cross-sectional view of a display device 1 according to a first embodiment. Light-emitting elements 11R, 11G, 11B each including an anode electrode 8, a hole transport layer 6, a light-emitting unit 10, an electron transport layer 5, and a cathode electrode 7 in this order on a substrate 9 are formed side by side on the substrate 9. The light-emitting unit 10 includes a first light-emitting layer 2 that emits red light (light of a first wavelength) along a y direction (first direction), a second light-emitting layer 3 that emits green light (light of a second wavelength) along the y direction (first direction), and a third light-emitting layer 4 that emits blue light along the y direction. The second light-emitting layer 3 and the third light-emitting layer 4 are arranged along an x direction (second direction) with respect to the first light-emitting layer 2. Note that the third light-emitting layer 4 is not limited to a configuration in which the third light-emitting layer 4 is positioned side-by-side with the first light-emitting layer 2 and the second light-emitting layer 3, that is, a configuration in which the first light-emitting layer 2, the second light-emitting layer 3, and the third light-emitting layer 4 lie on a straight line as illustrated in FIG. 1. The third light-emitting layer 4 may be arranged along a z direction (third direction) with respect to the first light-emitting layer 2, for example.

The first light-emitting layer 2, the second light-emitting layer 3, and the third light-emitting layer 4 are not limited to an aspect in which they are arranged in this order. For example, they may be arranged in the order of the second light-emitting layer 3, the first light-emitting layer 2, and the third light-emitting layer 4, or may be arranged in any order.

As described above, the light-emitting elements 11R, 11G, 11B include the first light-emitting layer 2, the second light-emitting layer 3, and the third light-emitting layer 4, respectively, that emit colors different from each other. The light-emitting elements 11R, 11G, 11B are separated from each other by a side wall 12.

The anode electrode 8 includes a conductive material and is electrically connected to the hole transport layer 6. The cathode electrode 7 includes a conductive material and is electrically connected to the electron transport layer 5.

At least one of the anode electrode 8 and the cathode electrode 7 includes a transparent conductive film. As the transparent conductive film, for example, ITO, IZO, ZnO, AZO, BZO, or the like is used. The transparent conductive film is formed by sputtering or the like.

Either one of the anode electrode 8 and the cathode electrode 7 may be formed of a metal. The metal is preferably Al, Cu, Au, Ag, or the like having a high reflectivity of visible light. At least one of the anode electrode 8 and the cathode electrode 7 is separated for each of the light-emitting elements 11R, 11G, 11B.

The hole transport layer 6 is formed of a p-type oxide semiconductor (eg., NiO, MgNiO, Cu₂O) or an organic material such as PEDOT:PSS/PVK. The hole transport layer 6 can be formed bycoating, a sputtering method, vapor deposition, or the like.

The first light-emitting layer 2, the second light-emitting layer 3, and the third light-emitting layer 4 include quantum dots. For example, CdSe/CdS, CdSe/ZnS, InP/ZnS, CIGS/ZnS, or the like may be used. The particle size of each of the quantum dots is approximately from 3 nm to 10 nm. Nanoparticles are dispersed in a solvent such as hexane to form a quantum dot layer by a spin coating method, an ink-jet method, or the like Nanoparticles composed of an inorganic material can increase the reliability of the quantum dot layer more than nanoparticles composed of an organic material.

The first light-emitting layer 2, the second light-emitting layer 3, and the third light-emitting layer 4 each can change in wavelength of emitted light by the particle size and material of the quantum dots. The first light-emitting layer 2, the second light-emitting layer 3, and the third light-emitting layer 4 each may include an organic material. The first light-emitting layer 2, the second light-emitting layer 3, and the third light-emitting layer 4, which emit light of different colors, are separated from each other by the side wall 12. They may be formed by performing masking for each of the first light-emitting layer 2, the second light-emitting layer 3, and the third light-emitting layer 4 and repeating vapor deposition, may be formed by mixing quantum dot phosphors of each color into a photosensitive resist and repeating a photolithography process, or may be formed using an ink-jet method.

The electron transport layer 5 is a mixture of nanoparticles having two or more different electron affinities, and is common to the first light-emitting layer 2, the second light-emitting layer 3, and the third light-emitting layer 4 of respective colors. In the case of three colors RGB, there are three electron affinities, and thus, the electron transport layer 5 is preferably a mixture of three types of nanoparticles having three electron affinities. In this way, the single electron transport layer 5 can enhance the luminous efficiency of each of the first light-emitting layer 2, the second light-emitting layer 3, and the third light-emitting layer 4 of the three colors RGB. When the nanoparticles of the electron transport layer 5 are composed of an inorganic compound, it is possible to increase reliability.

The electron transport layer 5 is preferably a mixture of three types of ZnO nanoparticles having particle sizes of 12 nm, 4 nm, and 3 nm, for example. As a result, the electron transport layer 5 can have electron affinities that enhance the luminous efficiency of each of the three types of first light-emitting layer 2, the second light-emitting layer 3, and the third light-emitting layer 4 In general, when the particle size of nanoparticles is reduced, a bandgap widens due to a quantum effect to reduce an electron affinity. The ZnO nanoparticles having particle sizes of 12 nm, 4 nm, and 3 nm have electron affinities of 3.9 eV, 3.5 eV, and 3.1 eV, respectively, and are mixed to realize the electron transport layer 5 having the three electron affinities.

The three types of nanoparticles of the electron transport layer 5 are composed of an identical material, and thus, are easily prepared by adjusting a synthesis time of the nanoparticles. In addition, they have an identical crystal structure, and thus, an electrical conductivity and the like are not significantly changed.

For imparting different electron affinities, for example, in Znt₁₋ₓMgₓO (0 ≤ X < 1), the composition may be changed, such as X = 0, 0.2, 0.4, to realize the three types of nanoparticles, or a different material such as TiO₂ may be used to realize the three types of nanoparticles. Alternatively, the particle size and composition may be changed simultaneously to realize the three types of nanoparticles.

The nanoparticles are prepared by a known technique, and a mixed solution in which the nanoparticles are mixed into an organic solvent such as ethanol is made into the electron transport layer 5 using a spin coating method, an ink-jet method, or the like. The electron transport layer 5 and the cathode electrode 7 are preferably not separated for each element because the production process is simple, but may be separated for each element.

In the present embodiment, the electron affinities of the first light-emitting layer 2, the second light-emitting layer 3, and the third light-emitting layer 4 of the three colors RGB were EML1 = 3.6 eV, EML2 = 3.3 eV, and EML3 = 2.9 eV, respectively. The electron transport layer 5 was a mixture of ZnO nanoparticles having particle sizes of 12 nm, 4 nm, and 3 nm, and the electron affinities were designated in descending order of magnitudes 3.9 eV (ETL1), 3.5 eV (ETL2), and 3.1 eV (ETL3). Here, the electron affinity of a light-emitting layer refers to the electron affinity of a light-emitting material included in the light-emitting layer.

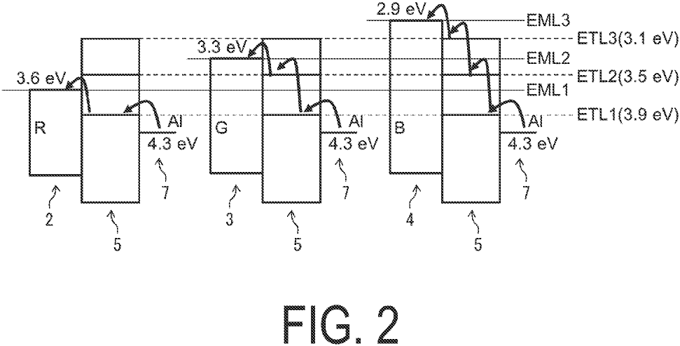

FIG. 2 is a diagram illustrating a flow of injecting electrons into the first light-emitting layer 2, the second light-emitting layer 3, and the third light-emitting layer 4 provided in the display device 1.

FIG. 2 illustrates a band diagram between each of the first light-emitting layer 2, the second light-emitting layer 3, and the third light-emitting layer 4, and the cathode electrode 7 formed of Al, and an arrow indicating a flow of electron injection from the cathode electrode 7 to each of the first light-emitting layer 2, the second light-emitting layer 3, and the third light-emitting layer 4, according to the first embodiment. The electrons are injected in order going from the one having a large electron affinity to the one having a small electron affinity as voltage is applied.

The electron transport layer 5 has the three electron affinities ETL1, ETL2, ETL3, and when a voltage is applied between the anode electrode 8 and the cathode electrode 7, electrons are first injected from the cathode electrode 7 into a location of the electron transport layer 5 having the largest electron affinity ETL1. Then, electrons are injected from the location having the electron affinity ETL1 into a location of the electron transport layer 5 having the second largest electron affinity ETL2. Next, electrons are injected from the location having the electron affinity ETL2 into a location of the electron transport layer 5 having the smallest electron affinity ETL3.

For the first light-emitting layer 2 having the electron affinity EML1, electrons are first injected from the cathode electrode 7 into the location having the electron affinity ETL1. Then, before injected to the location having the electron affinity ETL2, electrons can be injected from the location having the electron affinity ETL1 into the first light-emitting layer 2 having the electron affinity EML1.

For the second light-emitting layer 3 having the electron affinity EML2, electrons are first injected from the cathode electrode 7 into the location having the electron affinity ETL1. Then, electrons are injected from the location having the electron affinity ETL1 into the location having the electron affinity ETL2. Next, before injected into the location having the electron affinity ETL3, electrons can be injected from the location having the electron affinity ETL2 into the second light-emitting layer 3 having the electron affinity EML2.

For the third light-emitting layer 4 having the electron affinity EML3, electrons are first injected from the cathode electrode 7 into the location having the electron affinity ETL1. Then, electrons are injected from the location having the electron affinity ETL1 into the location having the electron affinity ETL2. Next, after injected from the location having the electron affinity ETL2 into the location having the electron affinity ETL3, electrons can be injected into the third light-emitting layer 4 having the electron affinity EML3.

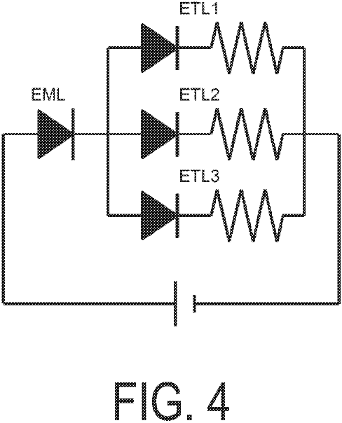

In this way, into each of the first light-emitting layer 2, the second light-emitting layer 3, and the third light-emitting layer 4, electrons are injected from each of the locations of the electron affinities ETL1, ETL2, ETL3 having a high luminous efficiency. Few electrons are injected from the other ETL. This will be described using a circuit diagram of FIG. 4.

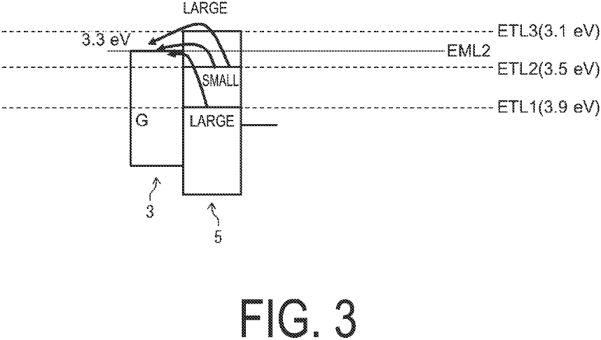

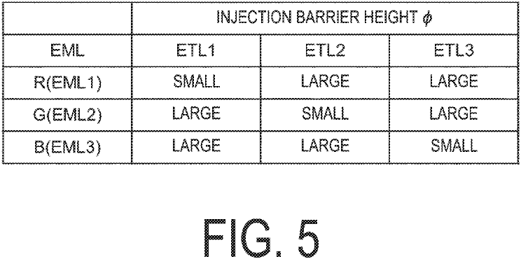

FIG. 3 is a diagram for describing injection of electrons from the electron transport layer 5 to the second light-emitting layer 3 provided in the display device 1. FIG. 4 is a circuit diagram of an equivalent circuit related to injection of electrons from the electron transport layer 5 to a light-emitting layer (the first light-emitting layer 2, or the second light-emitting layer 3, or the third light-emitting layer 4). FIG. 5 is a diagram for describing an injection barrier of electrons from the electron transport layer 5 into the first light-emitting layer 2, the second light-emitting layer 3, and the third light-emitting layer 4.

When the injection of electrons from the electron transport layer 5 to the light-emitting layer is illustrated in the circuit diagram, as illustrated in FIG. 4, the electron transport layer 5 can be indicated such that three series circuits each having a diode and a resistor are arranged in parallel.

The current of the diode can be represented by

$$\text{I = I0} \left[exp \left\{\text{q} \left(\text{V -} φ\right) / \text{nkT}\right\} - 1\right] .$$

Here, φ corresponds to an injection barrier height of the diode, and its magnitude correlates with the injection barrier from the electron transport layer 5 to the first light-emitting layer 2, the second light-emitting layer 3, or the third light-emitting layer 4. A current I of the diode increases exponentially with respect to a voltage, and the current I changes significantly due to the injection barrier height φ, and most of the current flows to the diode having a small injection barrier height φ.

For example, as illustrated in FIG. 3, consider a case where electrons are injected to the electron affinity EML2 of the second light-emitting layer 3 when electrons are injected from the electron transport layer 5 into the second light-emitting layer 3 that emits green light. The injection barrier of the electron transport layer 5 from the electron affinities ETL1, ETL2, ETL3 is 0.6 eV with injection from the electron affinity ETL1 (3.9 eV) to the electron affinity EML2 (3.3 eV), and is 0.2 eV with injection from the electron affinity ETL2 (3.5 eV) to the electron affinity EML2 (3.3 eV). In the case of the electron affinity ETL3, the injection barrier is 0.4 eV because electrons pass from the electron affinity ETL2 (3.5 eV) to the electron affinity ETL3 (3.1 eV). The injection barrier from the electron affinity ETL2 is the smallest in this manner, and thus, most electrons are injected from the electron affinity ETL2 to the second light-emitting layer 3.

The same applies to cases of the first light-emitting layer 2 and the third light-emitting layer 4, and the magnitude relationship of the injection barrier height φ is as shown in FIG. 5.

When the electron transport layer 5 has a plurality of electron affinities ETL1, ETL2, ETL3, as compared to a case where the electron transport layer 5 has a single electron affinity, electrons can be injected from the electron transport layer 5 at a low voltage appropriate for each of the first light-emitting layer 2, the second light-emitting layer 3, and the third light-emitting layer 4 of RGB.

Accordingly, by including, in the electron transport layer 5, a mixture obtained by appropriately selecting and mixing nanoparticles having an electron affinity with a high injection efficiency for each of the first light-emitting layer 2, the second light-emitting layer 3, and the third light-emitting layer 4 of respective colors as a first material, a second material, and a third material, it is possible to obtain the light-emitting elements 11R, 11G, 11B having high luminous efficiencies for different colors even when the electron transport layer 5 is common to the first light-emitting layer 2, the second light-emitting layer 3, and the third light-emitting layer 4

For this reason, the electron transport layer 5 preferably has the same number of different electron affinities as the number of colors of light emitted from the display device 1, and in the case of three colors, when the electron affinities of the first light-emitting layer 2, the second light-emitting layer 3, and the third light-emitting layer 4 are designated, in a descending order of magnitude, as the electron affinity EML1, the electron affinity EML2, and the electron affinity EML3, and the electron affinities of the electron transport layer 5 are designated, in a descending order of magnitude, as the electron affinity ETL1, the electron affinity ETL2, and the electron affinity ETL3, preferably,

$$\text{EML3} \leq \text{ETL3} < \text{EML2} \leq \text{ETL2} < \text{EML1} \leq \text{ETL1}$$

is satisfied. Electron injection from an electron affinity suitable for the light-emitting layer of each color is made possible, and the luminous efficiency of the light-emitting layer of each color can also be enhanced.

Furthermore, when a difference in electron affinity is 0.1 eV, current injection becomes easier by a factor of about 50, and thus, the difference in electron affinity of the nanoparticles among the first material, the second material, and the third material is preferably 0.1 eV or greater. It is possible to preferentially flow current to a suitable light-emitting layer among the first light-emitting layer 2, the second light-emitting layer 3, and the third light-emitting layer 4. In addition, since the difference in electron affinity among the first light-emitting layer 2, the second light-emitting layer 3, and the third light-emitting layer 4 of RGB is 0.3 eV or greater, if the difference in electron affinity of the nanoparticles is 0.3 eV or greater, it is possible to have the electron transport layer 5 include nanoparticles having a high injection efficiency for the first light-emitting layer 2, the second light-emitting layer 3, and the third light-emitting layer 4 of respective colors.

When x is larger in Zn₁₋ₓMgₓO, in general, when the electron affinity is smaller, an electron concentration is reduced, and a resistivity is increased. In addition, in general, the luminous efficiency of quantum dots decreases in the order of RGB (order in which the electron affinity decreases). Accordingly, increasing a volume ratio of nanoparticles having a small electron affinity makes it easier to inject electrons into the nanoparticles having a small electron affinity, so that it is possible to improve the luminous efficiency for a color having a lower luminous efficiency. In this way, the overall luminous efficiency of the display device 1 can be enhanced in a well-balanced manner. In addition, electrons are easily injected from the cathode electrode 7 into nanoparticles having a large electron affinity, and thus, it is preferable that the nanoparticles having a large electron affinity have the largest volume ratio in the vicinity of the interface of the cathode electrode 7. This makes it easier to inject electrons from the cathode electrode 7 into the electron transport layer 5. The volume ratio of the nanoparticles having a large electron affinity at the interface of the cathode electrode 7 may be 100%.

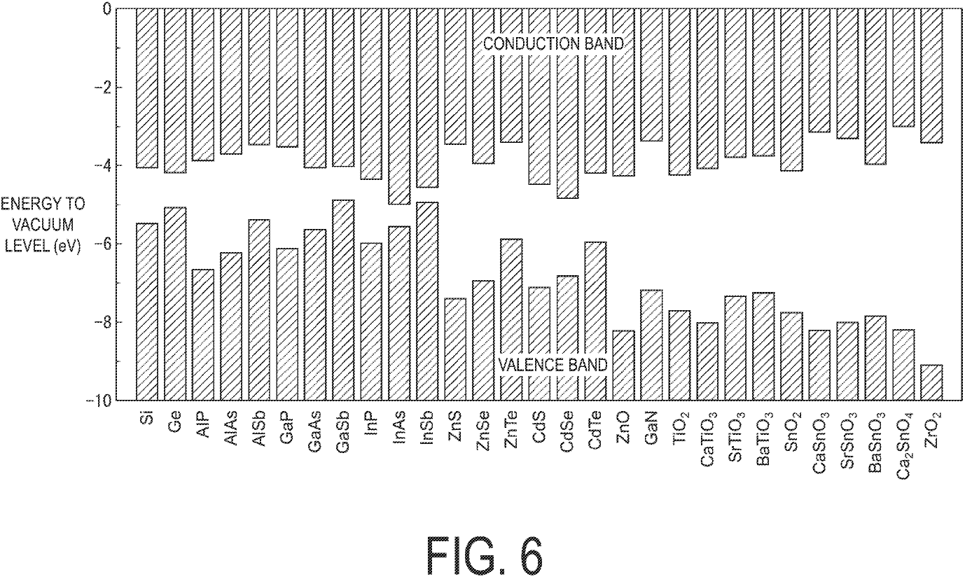

FIG. 6 is a graph showing the relationship between materials of the electron transport layer 5 and energies relative to the vacuum level.

As a material having the electron affinity ETL1, a material having the electron affinity ETL2, and a material having the electron affinity ETL3 of electron transport layer 5, it is possible to use materials different from each other For example, as a material having the electron affinity ETL1, TiO₂ (electron affinity of 4.2 eV) or SnO₂ (electron affinity of 4.2 eV) can be used. As a material having the electron affinity ETL2, GaP (electron affinity of 3.5 eV), AlSb (electron affinity of 3.4 eV), or ZrO₂ (electron affinity of 3.4 eV) can be used. As a material having the electron affinity ETL3, GaN (electron affinity of 3.2 eV), ZnS (electron affinity of 3.2 eV), ZnTe (electron affinity of 3.2 eV), Ca₂SnO₄ (electron affinity of 3.0 eV), CaSnO₃ (electron affinity of 3.2 eV), or the like can be used.

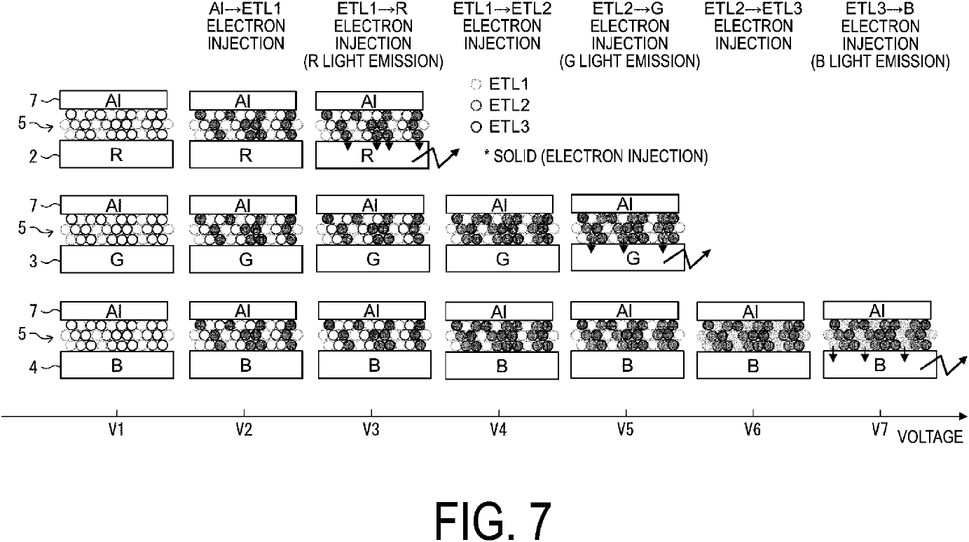

FIG. 7 is a diagram for describing an image for injecting electrons from the electron transport layer 5 into the first light-emitting layer 2, the second light-emitting layer 3, and the third light-emitting layer 4.

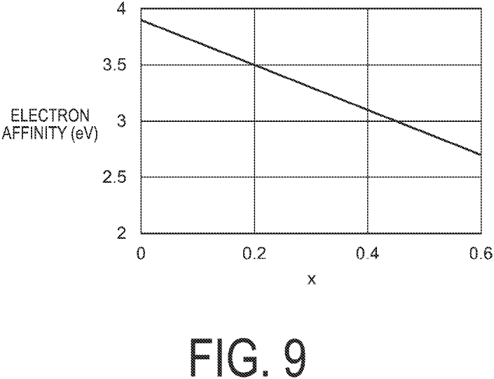

FIG. 9 illustrates a state in which a voltage applied between the cathode electrode 7 and the anode electrode 8 is increased in order from the left.

First, in a case where a voltage V1 is applied between the cathode electrode 7 and the anode electrode 8, electrons are not injected from the cathode electrode 7 to the electron transport layer 5. Next, when the voltage V1 increases to a voltage V2, electrons are injected from the cathode electrode 7 into the first material of the electron transport layer 5 having the electron affinity ETL1. Next, when the voltage V2 increases to a voltage V3, electrons are injected from the first material of the electron transport layer 5 having the electron affinity ETL1 into the first light-emitting layer 2, and the first light-emitting layer 2 emits red light.

Next, when the voltage V3 increases to a voltage V4, electrons are injected from the first material of the electron transport layer 5 having the electron affinity ETL1 into the second material of the electron transport layer 5 having the electron affinity ETL2. Then, when the voltage V4 increases to a voltage V5, electrons are injected from the second material of the electron transport layer 5 having the electron affinity ETL2 into the second light-emitting layer 3, and the second light-emitting layer 3 emits green light.

Next, when the voltage V5 increases to a voltage V6, electrons are injected from the second material of the electron transport layer 5 having the electron affinity ETL2 into the third material of the electron transport layer 5 having the electron affinity ETL3. Next, when the voltage V6 increases to a voltage V7, electrons are injected from the third material of the electron transport layer 5 having the electron affinity ETL3 into the third light-emitting layer 4, and the third light-emitting layer 4 emits blue light.

At the interface between the cathode electrode 7 including Al and the electron transport layer 5, the first material of the electron transport layer 5 having the electron affinity ETL1 preferably has a volume ratio greater than that of the second material of the electron transport layer 5 having the electron affinity ETL2, and the second material of the electron transport layer 5 having the electron affinity ETL2 preferably has a volume ratio greater than that of the third material of the electron transport layer 5 having the electron affinity ETL3. The first material of the electron transport layer 5 having the electron affinity ETL1 more preferably has a volume ratio of 100%. This is because electrons are more easily injected into the first material having the electron affinity ETL1 from the cathode electrode 7 than the second material having the electron affinity ETL2.

At the interface between the electron transport layer 5 and each of the first light-emitting layer 2, the second light-emitting layer 3, and the third light-emitting layer 4, the third material of the electron transport layer 5 having the electron affinity ETL3 preferably has a volume ratio greater than that of the second material of the electron transport layer 5 having the electron affinity ETL2, and the second material of the electron transport layer 5 having the electron affinity ETL2 preferably has a volume ratio greater than that of the first material of the electron transport layer 5 having the electron affinity ETL 1.

This is because when the volume ratios of the corresponding third material, second material, and first material of the electron transport layer 5 are largest, second largest, and smallest, respectively, in ascending order of luminous efficiencies of the quantum dots of the third light-emitting layer 4 of blue light, the second light-emitting layer 3 of green light, and the first light-emitting layer 2 of red light, it is possible to improve the luminous efficiency balance of the display device 1.

From the cathode electrode 7 to the first light-emitting layer 2, the second light-emitting layer 3, and the third light-emitting layer 4, preferably, the volume ratios of the third material of the electron transport layer 5 having the electron affinity ETL3 and the second material of the electron transport layer 5 having the electron affinity ETL2 gradually increase, and the volume ratio of the first material of the electron transport layer 5 having the electron affinity ETL1 decreases.

This is because no barrier is generated for electron injection along the direction in which electrons flow from the first material having the electron affinity ETL1 to the second material having the electron affinity ETL2 and from the second material having the electron affinity ETL2 to the third material having the electron affinity ETL3, that is, from the cathode electrode 7 to the first light-emitting layer 2, the second light-emitting layer 3, and the third light-emitting layer 4, and it is possible to minimize the voltage in the electron transport layer 5.

The electron transport layer 5 including a mixture in which the first material having the electron affinity ETL1, the second material having the electron affinity ETL2, and the third material having the electron affinity ETL3 are mixed can be formed by, for example, spin-coating a nanoparticle mixed solution of the second material and the third material (volume ratios satisfying second material < third material), and spin-coating a nanoparticle solution of the first material before drying.

Alternatively, the electron transport layer 5 including the mixture can be formed by preparing a plurality of solutions having different concentrations of the nanoparticle mixed solution of the first material, the second material, and the third material (proportions of the first material, the second material, and the third material), and coating the plurality of solutions a plurality of times to form layers, thereby having a concentration distribution in a film thickness direction.

In this manner, even when the electron transport layer 5 common to the first light-emitting layer 2, the second light-emitting layer 3, and the third light-emitting layer 4 is formed, light of each of the colors of the first light-emitting layer 2, the second light-emitting layer 3, and the third light-emitting layer 4 can be emitted at a low voltage to enhance the luminous efficiency.

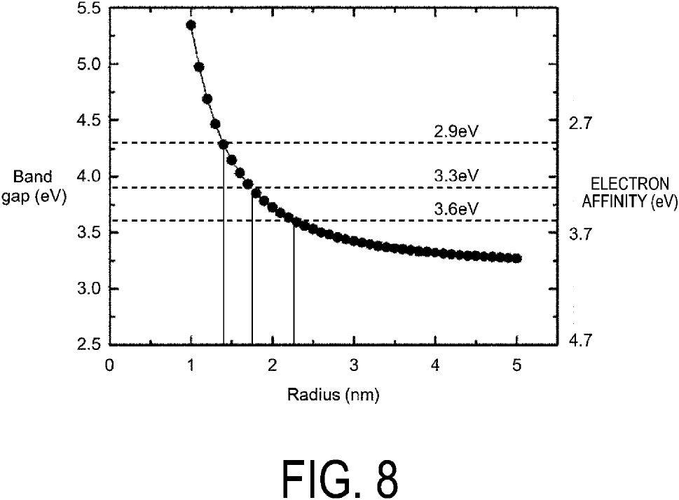

FIG. 8 is a graph showing the relationship among a radius of ZnO nanoparticles, a bandgap, and an electron affinity.

The first material, the second material, and the third material of the mixture included in the electron transport layer 5 include nanoparticles, and preferably include ZnO. When the particle size of the ZnO nanoparticles is reduced, the bandgap widens due to the quantum effect and the electron affinity decreases, and thus, it is possible to realize the electron transport layer 5 having three types of electron affinities by changing the particle sizes of the first material, the second material, and the third material.

The particle size of the nanoparticles of the first material is preferably 4.5 nm or greater. This is because in this case, the radius of the nanoparticles of the first material is 2.25 nm or greater, and as shown in FIG. 8, the electron affinity of the first material is equal to or greater 3.6 eV of an electron affinity corresponding to the electron affinity of the first light-emitting layer 2.

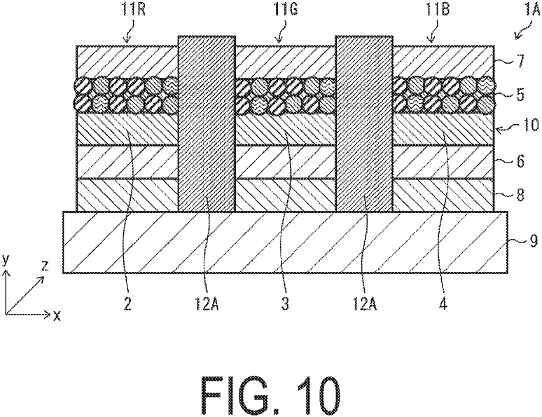

The particle size of the nanoparticles of the second material is preferably 3.5 nm or greater and smaller than 4.5 nm. This is because in this case, the radius of the nanoparticles of the second material is 1.75 nm or greater and 2.25 nm or smaller, and as shown in FIG. 10, the electron affinity of the second material is an electron affinity of 3.3 eV or greater corresponding to the electron affinity of the second light-emitting layer 3, and an electron affinity of smaller than 3.6 eV corresponding to the electron affinity of the first light-emitting layer 2.

The particle size of the nanoparticles of the third material is preferably 28 nm or greater and smaller than 3.5 nm. This is because in this case, the radius of the nanoparticles of the third material is 1.4 nm or greater and 1.75 nm or smaller, and as shown in FIG. 8, the electron affinity of the third material is equal to or greater than 2.9 eV of an electron affinity corresponding to the electron affinity of the third light-emitting layer 4, and smaller than 3.3 eV of an electron affinity corresponding to the electron affinity of the second light-emitting layer 3.

FIG. 9 is a graph showing the relationship between a composition x of Zn₁₋ₓMgₓO having a particle size of 12 nm and an electron affinity.

The first material, second material, and third material of the mixture included in the electron transport layer 5 include nanoparticles having a particle size of 12 nm, and preferably include Zn₁₋ₓMgₓO. When the composition x of Zn₁₋ₓMgₓO is changed, the electron affinity is changed. Thus, it is possible to realize the electron transport layer 5 having three types of electron affinities by making the composition x different among the first material, the second material, and the third material.

In the first material, x above is preferably 0 or greater and 0.15 or less. This is because in this case, as shown in FIG. 9, the electron affinity ETL1 of the first material is greater than 3.6 eV of the electron affinity EML1 of the first light-emitting layer 2.

In the second material, x above is preferably greater than 0.15 and 0.3 or less. This is because in this case, as shown in FIG. 9, the electron affinity ETL2 of the second material is greater than 3.3 eV of the electron affinity EML2 of the second light-emitting layer 3, and is equal to or smaller than 3.6 eV of the electron affinity EML3 of the first light-emitting layer 2.

In the third material, x above is preferably greater than 0.3 and 0.5 or less. This is because in this case, as shown in FIG. 9, the electron affinity ETL3 of the third material is greater than 2.9 eV of the electron affinity EML3 of the third light-emitting layer 4, and is equal to or smaller than 3.3 eV of the electron affinity EML2 of the second light-emitting layer 3.

In this manner, the display device 1 includes the first light-emitting layer 2 and the second light-emitting layer 3 arranged along the x direction intersecting the y direction to emit red light of the first wavelength and green light of the second wavelength different from the first wavelength along the y direction, the electron transport layer 5 common to the first light-emitting layer 2 and the second light-emitting layer 3 to supply electrons to the first light-emitting layer 2 and the second light-emitting layer 3, and the cathode electrode 7 configured to supply electrons to the electron transport layer 5.

The electron transport layer 5 includes the mixture in which the first material and the second material are mixed. The electron affinity of the first light-emitting layer 2 is equal to or smaller than the electron affinity of the first material. The electron affinity of the second material is smaller than the electron affinity of the first material. The electron affinity of the second light-emitting layer 3 is equal to or smaller than the electron affinity of the second material

The electron affinities of the first material and the second material included in the electron transport layer 5 are preferably different from each other by 0.1 eV or greater. When the difference in electron affinity is 0.1 eV, current injection becomes easier by a factor of about 50, so that it is possible to preferentially flow current to a material having an appropriate electron affinity.

The first material and the second material of the electron transport layer 5 each preferably include an inorganic compound. It is possible to increase reliability by using an inorganic compound

The first light-emitting layer 2 and the second light-emitting layer 3 preferably include quantum dots. The quantum dots are more reliable than an organic light-emitting material, and can be easily formed using a coating method or an ink-jet method.

The display device 1 further includes the third light-emitting layer 4 arranged along the x direction with respect to the first light-emitting layer 2 and the second light-emitting layer 3 to emit blue light of the third wavelength different from the first wavelength and the second wavelength along the y direction.

The third material is further mixed in the mixture of the electron transport layer 5. The electron affinity of the third material is smaller than the electron affinity of the second material. The electron affinity of the third light-emitting layer 4 is equal to or smaller than the electron affinity of the third material.

The electron affinity of the first light-emitting layer 2 and the electron affinity of the second light-emitting layer 3 are preferably different from each other. This makes it possible to enhance the luminous efficiencies of the first light-emitting layer 2 and the second light-emitting layer 3 having the electron affinities different from each other by the common electron transport layer.

In a case where the electron affinity of the first light-emitting layer 2 is equal to or greater than the electron affinity of the second light-emitting layer 3, it is preferable that the electron affinity of the first material is equal to or greater than the electron affinity of the first light-emitting layer 2, the electron affinity of the first light-emitting layer 2 is equal to or greater than the electron affinity of the second material, and the electron affinity of the second material is equal to or greater than the electron affinity of the second light-emitting layer 3. This can make it possible to increase the luminous efficiencies of the first light-emitting layer 2 and the second light-emitting layer 3 having the electron affinities different from each other by the common electron transport layer 5 including the mixture of the first material and the second material.

The first material and the second material preferably include nanoparticles. When the particle size of the nanoparticles is decreased, the bandgap widens due to the quantum effect, and the electron affinity is decreased. For this reason, it is possible to realize the electron transport layer 5 having a plurality of types of electron affinities by changing the particle sizes of the first material and the second material.

The first material and the second material are composed of Zn₁₋ₓMgₓO (0 ≤ x < 1), and the composition (x) or the particle size is preferably different between the first material and the second material. When the particle size of the nanoparticles of Zn₁₋ ₓMgₓO (0 ≤ x < 1) is decreased, the bandgap widens due to the quantum effect, and the electron affinity is decreased, and thus it is possible to realize the electron transport layer 5 having a plurality of types of electron affinities by changing the particle sizes of the first material and the second material.

The first material, the second material, and the third material include nanoparticles, and the volume ratios of the first material, the second material, and the third material included in the electron transport layer 5 preferably become larger in ascending order of magnitudes of the electron affinities of the first material, the second material, and the third material. This makes it easy to inject electrons into nanoparticles having a small electron affinity, so that it is possible to improve the luminous efficiency more easily for a color having a lower luminous efficiency.

The first material, the second material, and the third material include nanoparticles, and the volume ratios of the first material, the second material, and the third material included in the electron transport layer 5 preferably become larger in descending order of magnitudes of the electron affinities in the vicinity of the interface with the cathode electrode 7. This makes it easier to inject electrons from the cathode electrode 7 into the electron transport layer 5.

The first material, the second material, and the third material include nanoparticles, and the volume ratios of the first material, the second material, and the third material included in the electron transport layer 5 preferably become larger in ascending order of magnitudes of the electron affinities in the vicinity of the interface with the first light-emitting layer 2 and the second light-emitting layer 3. This makes it possible to improve the luminous efficiency balance for a large number of materials in the electron transport layer 5 that correspond to colors of emitted light ascending in order of luminous efficiencies of the quantum dots.

The first material, the second material, and the third material include nanoparticles, and the nanoparticles having the largest electron affinity among the first material, the second material, and the third material preferably decrease from the cathode electrode 7 side toward the first light-emitting layer 2, the second light-emitting layer 3, and the third light-emitting layer 4 side. This does not generate a barrier against electron injection in the order of the third material, the second material, and the first material, as in a direction in which electrons flow, so that it is possible to minimize the voltage in the electron transport layer 5.

Nanoparticles other than the nanoparticles having the largest electron affinity preferably increase from the cathode electrode 7 side toward the first light-emitting layer 2 and the second light-emitting layer 3 side. This does not generate a barrier against electron injection in the order of the third material, the second material, and the first material, as in a direction in which electrons flow, so that it is possible to minimize the voltage in the electron transport layer 5.

The first material, the second material, and the third material preferably include at least one of TiO₂, and SnO₂, at least one of GaP, AlSb, and ZrO₂, and at least one of GaN, ZnS, ZnTe, Ca₂SnO₄, and CaSnO_{3.} In this way, different materials are used for the first material, the second material, and the third material, and thus it is possible to realize the electron transport layer 5 having three types of electron affinities.

The display device 1 preferably further includes the side wall 12 disposed between the first light-emitting layer 2 and the second light-emitting layer 3 and formed reaching the electron transport layer 5 to separate the first light-emitting layer 2 and the second light-emitting layer 3. As a result, the electron transport layer 5 is not separated for each element such as the first light-emitting layer 2 and the second light-emitting layer 3, and thus a process of forming the electron transport layer 5 is simplified.

FIG. 10 is a cross-sectional view of a display device 1A according to a modified example of the first embodiment. Constituent elements similar to the constituent elements described above are given the same reference numerals, and detailed descriptions thereof are not repeated.

The display device 1A may further include a side wall 12A disposed between the first light-emitting layer 2 and the second light-emitting layer 3 and formed extending through the electron transport layer 5 and the cathode electrode 7 to separate the first light-emitting layer 2 and the second light-emitting layer 3. The side wall 12A separates the electron transport layer 5 and the cathode electrode 7 for each of the light-emitting elements 11R, 11G, 11B.

Note that in the present embodiment, an example has been described in which the electron affinities of the first light-emitting layer 2, the second light-emitting layer 3, and the third light-emitting layer 4 of the three colors RGB are EML1 = 3.6 eV, EML2 = 3.3 eV, EML3 = 2.9 eV and in which the electron affinity of the light-emitting layer having the shorter emission wavelength is smaller, but the present invention is not limited thereto. The present invention can be applied even when the electron affinity of the light-emitting layer having a shorter emission wavelength is larger. For example, in a case where the first light-emitting layer 2 that emits red light includes CdTe, the second light-emitting layer 3 that emits green light includes CdSe, the third light-emitting layer 4 that emits blue light includes ZnSe, the electron affinities of the respective light-emitting layers are EML1 = 3.2 eV, EML2 = 3.3 eV, and EML3 = 3.1 eV, and ionization potentials of the respective light-emitting layers are 5.2 eV, 5.6 eV, and 5.8 eV, the electron affinity EML2 = 3.3 eV of the second light-emitting layer 3 having a shorter emission wavelength is larger than the electron affinity EML1 = 3.2 eV of the first light-emitting layer 2 having a longer emission wavelength

### Second Embodiment

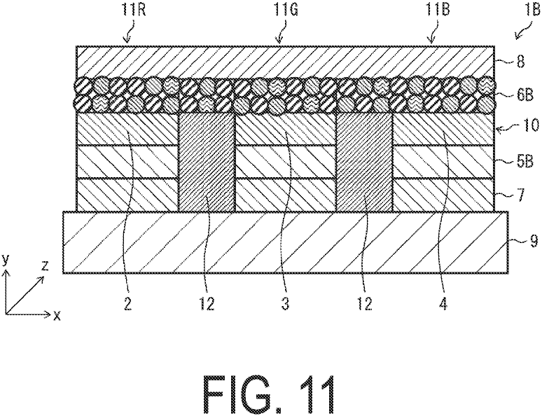

FIG. 11 is a cross-sectional view of a display device 1B according to a second embodiment. Constituent elements similar to the constituent elements described above are given the same reference numerals, and detailed descriptions thereof are not repeated.

Light-emitting elements 11R, 11G, 11B each including a cathode electrode 7, an electron transport layer 5B, a light-emitting unit 10, a hole transport layer 6B, and an anode electrode 8 in this order on a substrate 9 are formed side by side on the substrate 9. The light-emitting unit 10 includes a first light-emitting layer 2, a second light-emitting layer 3, and a third light-emitting layer 4 having different ionization potentials. The light-emitting elements 11R, 11G, 11B are separated by a side wall 12.

The first light-emitting layer 2, the second light-emitting layer 3, and the third light-emitting layer 4 are not limited to an aspect in which they are arranged in this order. For example, they may be arranged in the order of the second light-emitting layer 3, the first light-emitting layer 2, and the third light-emitting layer 4, or may be arranged in any order.

The cathode electrode 7 includes a conductive material and is electrically connected to the electron transport layer 5B.

The anode electrode 8 includes a conductive material and is electrically connected to the hole transport layer 6B.

At least one of the cathode electrode 7 and the anode electrode 8 includes a transparent conductive film. As the transparent conductive film, for example, ITO, IZO, ZnO, AZO, BZO, or the like is used. The transparent conductive film is formed by sputtering or the like.

Either one of the cathode electrode 7 and the anode electrode 8 may be formed of a metal. The metal is preferably Al, Cu, Au, or Ag having a high reflectivity of visible light. At least one of the cathode electrode 7 and the anode electrode 8 is separated for each of the light-emitting elements 11R, 11G, 11B.

The electron transport layer 5B is formed of an n-type oxide semiconductor (e.g., ZnO, Zn₁₋ₓMgₓO (0 ≤ X < 1), TiO₂, SnO₂). The electron transport layer 5B may be nanoparticles or a continuous film. The electron transport layer 5B can be formed by coating, a sputtering method, vapor deposition, or the like.

The hole transport layer 6B is a mixture of nanoparticles having two or more different ionization potentials, and is common to the light-emitting elements 11R, 11G, 11B. It is possible to improve the reliability of the light-emitting elements 11R, 11G, 11B by using an inorganic compound.

For example, the hole transport layer 6B is a mixture obtained by mixing nanoparticles having a particle size of 12 nm in which, in Ni₁₋ₓMgₓO (0 ≤ X < 1), X is 0, 0.25, and 0.5 The ionization potentials are 5.4 eV, 5.6 eV, and 5.8 eV, respectively.

To cause the hole transport layer 6B to have different ionization potentials, different materials such as Cu₂O, NiO, and NiO₁₋ₓ(LaNiO₃)ₓ may be used for the hole transport layer 6B. Nanoparticles of each material are prepared by a known technique, and a mixed solution obtained by mixing the nanoparticles into an organic solvent such as ethanol is used to form the hole transport layer 6B using a spin coating method, an ink-jet method, or the like. Although it is preferable that the hole transport layer 6B and the anode electrode 8 not be separated for each of the light-emitting elements 11R, 11G, 11B so that a production process is simple, the hole transport layer 6B and the anode electrode 8 may be separated for each of the light-emitting elements 11R, 11G, 11B.

In the present embodiment, the light-emitting unit 10 included the first light-emitting layer 2 of red light including InP as a core material (ionization potential of 5.4 eV), the second light-emitting layer 3 of green light including CdSe (ionization potential of 5.6 eV), and the third light-emitting layer 4 of blue light including ZnSe (ionization potential of 5.8 eV).

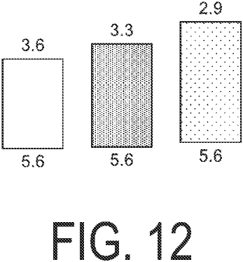

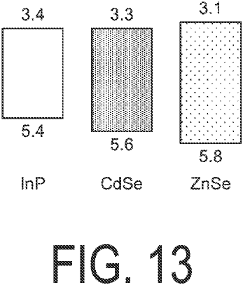

FIG. 12 is a diagram for describing electron levels of the light-emitting layers provided in the display device 1 according to the first embodiment. FIG. 13 is a diagram for describing electron levels of the light-emitting layers provided in the display device 1A according to the second embodiment.

In the first embodiment, quantum dots emitting light of different colors have different electron affinities, and thus, a configuration in which the electron transport layer 5 includes nanoparticles having different electron affinities, and the electron transport layer 5 is common to the light-emitting elements 11R, 11G, 11B, as illustrated in FIG. 1, is employed. If materials of core portions of quantum dots are identical, ionization potentials are substantially identical. In contrast, in the second embodiment, a configuration in which for quantum dots having different ionization potentials, the hole transport layer 6B includes nanoparticles having different ionization potentials, and the hole transport layer 6B is common to the light-emitting elements 11R, 11G, 11B, as illustrated in FIG. 11, is employed. The ionization potential of the quantum dot depends mainly on the core material. As illustrated in FIG. 13, for example, when the core material is CdSe, the ionization potential is approximately 5.6 eV, when the core material is InP, the ionization potential is approximately 5.4 eV, when the core material is ZnSe, the ionization potential is approximately 5.8 eV, and when the core material is InN, the ionization potential is approximately 6.5 eV.

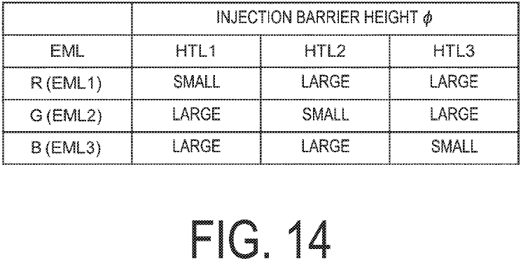

FIG. 14 is a diagram for describing an injection barrier of holes from the hole transport layer 6B to the first light-emitting layer 2, the second light-emitting layer 3, and the third light-emitting layer 4. The hole injection to each quantum dot can be described in the same way as in the electron injection of the electron transport layer 5. The magnitude relationship of the injection barrier height is as shown in FIG. 14.

As compared to a case where the hole transport layer 6 having a single ionization potential is used, the hole transport layer 6B including nanoparticles having different ionization potentials can inject holes at a low voltage suitable for each of the first light-emitting layer 2, the second light-emitting layer 3, and the third light-emitting layer 4. Accordingly, by appropriately selecting and mixing nanoparticles having an ionization potential at which injection efficiency is increased for each of the first light-emitting layer 2, the second light-emitting layer 3, and the third light-emitting layer 4, even when the hole transport layer 6B is common to the first light-emitting layer 2, the second light-emitting layer 3, and the third light-emitting layer 4, it is possible to obtain the display device 1B having high luminous efficiencies for the respective light-emitting layers.

Accordingly, the hole transport layer 6B preferably has the same number of types of different ionization potentials as the number of quantum core materials, and when the ionization potential of the first light-emitting layer 2 is designated as EML1, the ionization potential of the second light-emitting layer 3 is designated as EML2, and the ionization potential of the third light-emitting layer 4 is designated as EML3 in ascending order of magnitudes of ionization potentials of the light-emitting layers, and the ionization potential of the first material of the hole transport layer 6B is designated as HTL1, the ionization potential of the second material of the hole transport layer 6B is designated as HTL2, and the ionization potential of the third material of the hole transport layer 6B is designated as HTL3, HTL1 ≤ EML1 < HTL2 ≤ EML2 < HTL3 ≤ EML3 is preferably satisfied. Hole injection from the hole transport layer 6B suitable for each element becomes possible, and the luminous efficiency can be enhanced for each of the light-emitting elements 11R, 11G, 11B.

In addition, when a difference in ionization potential is 0.1 eV, current injection becomes easier by a factor of about 50, and thus, the difference in ionization potential of the nanoparticles among the first material, the second material, and the third material is preferably 0.1 eV or greater. It is possible to preferentially flow current to a suitable light-emitting layer among the first light-emitting layer 2, the second light-emitting layer 3, and the third light-emitting layer 4.

Furthermore, in Ni₁₋ₓMgₓO, when the composition x is large, in general, when the ionization potential is large, the carrier concentration is reduced to increase the resistivity. By increasing the volume ratio of nanoparticles having a large ionization potential, the conductivity of the nanoparticles having a large ionization potential can be improved, and the luminous efficiency of a color having a lower luminous efficiency can be improved, so that it is possible to increase the overall luminous efficiency in a well-balanced manner. Furthermore, holes are easily injected from the anode electrode 8 into nanoparticles having a small ionization potential, and thus, in the vicinity of the interface between the anode electrode 8 and the hole transport layer 6, the nanoparticles having a small ionization potential preferably have the largest volume ratio This facilitates hole injection from the anode electrode 8 into the hole transport layer 6.

At the interface described above, the volume ratio of nanoparticles having a small ionization potential may be 100%.

As described above, the display device 1B includes the first light-emitting layer 2 and the second light-emitting layer 3 arranged along the x direction intersecting the y direction to emit red light of the first wavelength and green light of the second wavelength different from the first wavelength along the y direction, the hole transport layer 6B common to the first light-emitting layer 2 and the second light-emitting layer 3 to supply holes to the first light-emitting layer 2 and the second light-emitting layer 3, and the anode electrode 8 to supply holes to the hole transport layer 6B.

The hole transport layer 6B includes a mixture in which the first material and the second material are mixed. The ionization potential of the first light-emitting layer 2 is equal to or greater than the ionization potential of the first material. The ionization potential of the second material is greater than the ionization potential of the first material. The ionization potential of the second light-emitting layer 3 is equal to or greater than the ionization potential of the second material.

The display device 1B preferably further includes the third light-emitting layer 4 arranged along the x direction with respect to the first light-emitting layer 2 and the second light-emitting layer 3 to emit blue light of the third wavelength different from the first and second wavelengths along the y direction.

The third material is preferably further mixed into the mixture of the hole transport layer 6B. This makes it possible to realize the hole transport layer 6B having three types of ionization potentials.

Preferably, the ionization potential of the third material is greater than the ionization potential of the second material, and the ionization potential of the third light-emitting layer 4 is equal to or greater than the ionization potential of the third material. This allows hole injection from the material of the hole transport layer 6B having an ionization potential suitable for each light-emitting element, so that it is possible to increase the luminous efficiency for each light-emitting element.

The ionization potential of the first light-emitting layer 2 and the ionization potential of the second light-emitting layer 3 are preferably different from each other. This allows the hole transport layer 6B to be common to the light-emitting elements 11R, 11G, 11B.

The material of the first light-emitting layer 2 and the material of the second light-emitting layer 3 are preferably different from each other. This allows the ionization potential of the first light-emitting layer 2 and the ionization potential of the second light-emitting layer 3 to be different from each other.

In a case where the ionization potential of the first light-emitting layer 2 is smaller than the ionization potential of the second light-emitting layer 3, it is preferable that the ionization potential of the first material is equal to or smaller than the ionization potential of the first light-emitting layer 2, the ionization potential of the first light-emitting layer 2 is smaller than the ionization potential of the second material, and the ionization potential of the second material is equal to or smaller than the ionization potential of the second light-emitting layer 3. This can increase the luminous efficiencies of the first light-emitting layer 2 and the second light-emitting layer 3 having the ionization potentials different from each other by the common hole transport layer 6B including the mixture of the first material and the second material.

The first material and the second material preferably include nanoparticles. This allows the compositions and materials of the nanoparticles to be different, so that it is possible to realize the hole transport layer 6B having a plurality of types of ionization potentials.

Preferably, the first material and the second material include nanoparticles and are composed of Ni₁₋ₓMgₓO (0 ≤ x <1), and the composition (x) is different between the first material and the second material. This allows the composition (x) of Ni₁₋ₓMgₓO (0 ≤ x < 1) to be made different between the first material and the second material, so that it is possible to realize the hole transport layer 6B having a plurality of types of ionization potentials.

The first material, the second material, and the third material include nanoparticles, and the volume ratios of the first material, the second material, and the third material included in the hole transport layer 6B preferably become larger in descending order of magnitudes of the ionization potentials of the first material, the second material, and the third material. This facilitates hole injection into nanoparticles having a large ionization potential, so that it is possible to improve the luminous efficiency of a color having a lower luminous efficiency.

The first material, the second material, and the third material include nanoparticles, and the volume ratios of the first material, the second material, and the third material included in the hole transport layer 6B are preferably larger in ascending order of magnitudes of the ionization potentials of the first material, the second material, and the third material in the vicinity of the interface with the anode electrode 8. This facilitates hole injection from the anode electrode 8 into the hole transport layer 6B.

The first material, the second material, and the third material include nanoparticles, and the volume ratios of the first material, the second material, and the third material included in the hole transport layer 6B are preferably larger in descending order of magnitudes of the ionization potentials of the first material, the second material, and the third material in the vicinity of the interface with the first light-emitting layer 2, the second light-emitting layer 3, and the third light-emitting layer 4. This facilitates hole injection into nanoparticles having a large ionization potential, so that it is possible to improve the luminous efficiency of a color having a lower luminous efficiency.

The first material, the second material, and the third material include nanoparticles, and the nanoparticles having the smallest ionization potential among the first material, the second material, and the third material preferably decrease from the anode electrode 8 side toward the first light-emitting layer 2, the second light-emitting layer 3, and the third light-emitting layer 4 side. This does not generate a barrier against hole injection in the order of the third material, the second material, and the first material, as in a direction in which holes flow, so that it is possible to minimize the voltage in the hole transport layer 6B.

Nanoparticles other than the nanoparticles having the smallest ionization potential preferably increase from the anode electrode 8 side toward the first light-emitting layer 2, the second light-emitting layer 3, and the third light-emitting layer 4 side. This does not generate a barrier against hole injection in the order of the third material, the second material, and the first material, as in a direction in which holes flow, so that it is possible to minimize the voltage in the hole transport layer 6B.

The display device 1B preferably further includes the side wall 12 disposed between the first light-emitting layer 2 and the second light-emitting layer 3 and formed reaching the hole transport layer 6B to separate the first light-emitting layer 2 and the second light-emitting layer 3. As a result, the hole transport layer 6B is not separated for each element, such as the first light-emitting layer 2 and the second light-emitting layer 3, and thus, a process of forming the hole transport layer 6B is simplified.

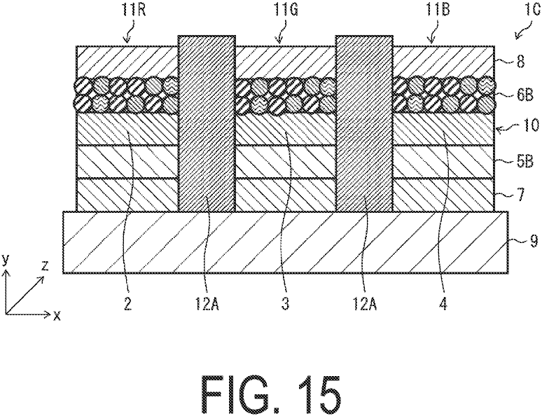

FIG. 15 is a cross-sectional view of a display device 1C according to a modified example of the second embodiment. Constituent elements similar to the constituent elements described above are given the same reference numerals, and detailed descriptions thereof are not repeated.

The display device 1C may further include a side wall 12A disposed between the first light-emitting layer 2 and the second light-emitting layer 3 and formed extending through the hole transport layer 6B and the anode electrode 8 to separate the first light-emitting layer 2 and the second light-emitting layer 3. The side wall 12A separates the hole transport layer 6B and the anode electrode 8 for each of the light-emitting elements 11R, 11G, 11B.

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in each of the embodiments.

### REFERENCE SIGNS LIST

1 Display device
2 First light-emitting layer
3 Second light-emitting layer
4 Third light-emitting layer
5 Electron transport layer
6 Hole transport layer
7 Cathode electrode
8 Anode electrode
9 Substrate

1. A display device comprising:
a first light-emitting layer configured to emit light of a first wavelength along a first direction;
a second light-emitting layer arranged with respect to the first light-emitting layer along a second direction intersecting the first direction and configured to emit light of a second wavelength different from the first wavelength along the first direction;
an electron transport layer common to the first light-emitting layer and the second light-emitting layer and configured to supply electrons to the first light-emitting layer and the second light-emitting layer; and
a cathode electrode configured to supply the electrons to the electron transport layer,
wherein the electron transport layer includes a mixture in which a first material and a second material are mixed,
an electron affinity of the first light-emitting layer is equal to or smaller than an electron affinity of the first material,
an electron affinity of the second material is smaller than the electron affinity of the first material, and
an electron affinity of the second light-emitting layer is equal to or smaller than the electron affinity of the second material.

2. The display device according to claim 1,
wherein the electron affinity of the first material and the electron affinity of the second material included in the electron transport layer are different from each other by 0.1 eV or greater.

3-4. (canceled)

5. The display device according to claim 1, further comprising
a third light-emitting layer arranged with respect to the first light-emitting layer and the second light-emitting layer along a third direction intersecting the first direction and configured to emit light of a third wavelength different from the first wavelength and the second wavelength along the first direction,
wherein a third material is further mixed in the mixture of the electron transport layer,
an electron affinity of the third material is smaller than the electron affinity of the second material, and
an electron affinity of the third light-emitting layer is equal to or smaller than the electron affinity of the third material.

6. The display device according to claim 1,
wherein the electron affinity of the first light-emitting layer and the electron affinity of the second light-emitting layer are different from each other.

7. The display device according to claim 1,
wherein, in a case where the electron affinity of the first light-emitting layer is equal to or greater than the electron affinity of the second light-emitting layer,
the electron affinity of the first material is equal to or greater than the electron affinity of the first light-emitting layer,
the electron affinity of the first light-emitting layer is equal to or greater than the electron affinity of the second material, and
the electron affinity of the second material is equal to or greater than the electron affinity of the second light-emitting layer.

8. The display device according to any one of claim 1,
wherein the first material and the second material include nanoparticles,
wherein the first material and the second material are composed of Zn₁₋ₓMgₓO (0 ≤ x < 1), and
a composition (x) or a particle size is different between the first material and the second material.

9-14. (canceled)

15. The display device according to claim 5,
wherein the first material, the second material, and the third material include nanoparticles,
the first material, the second material, and the third material include ZnO,
a particle size of the nanoparticles of the first material is equal to or greater than 4.5 nm,
a particle size of the nanoparticles of the second material is equal to or greater than 3.5 nm and smaller than 4.5 nm, and
a particle size of nanoparticles of the third material is equal to or greater than 2.8 nm and smaller than 3.5 nm.

16. The display device according to claim 5,
wherein the first material, the second material, and the third material each include nanoparticles composed of Zn₁₋ₓMgₓO,
the nanoparticles of the first material satisfy 0 ≤ x ≤ 0.15,
the nanoparticles of the second material satisfy 0.15 < x ≤ 0.3, and
the nanoparticles of the third material satisfy 0.3 < x ≤ 0.5.

17. (canceled)

18. A display device comprising:
a first light-emitting layer and a second light-emitting layer arranged along a second direction intersecting a first direction and configured to emit light of a first wavelength and light of a second wavelength different from the first wavelength, respectively, along the first direction;
a hole transport layer common to the first light-emitting layer and the second light-emitting layer and configured to supply holes to the first light-emitting layer and the second light-emitting layer; and
an anode electrode configured to supply the holes to the hole transport layer,
wherein the hole transport layer includes a mixture in which a first material and a second material are mixed,
an ionization potential of the first light-emitting layer is equal to or greater than an ionization potential of the first material,
an ionization potential of the second material is greater than the ionization potential of the first material, and
an ionization potential of the second light-emitting layer is equal to or greater than the ionization potential of the second material.

19. The display device according to claim 18, further comprising
a third light-emitting layer arranged along the second direction with respect to the first light-emitting layer and the second light-emitting layer and configured to emit light of a third wavelength different from the first wavelength and the second wavelength along the first direction,
wherein a third material is further mixed into the mixture of the hole transport layer,
an ionization potential of the third material is greater than the ionization potential of the second material, and
an ionization potential of the third light-emitting layer is equal to or greater than the ionization potential of the third material.

20. The display device according to claim 18,
wherein the ionization potential of the first light-emitting layer and the ionization potential of the second light-emitting layer are different from each other.

21. The display device according to claim 18,
wherein a material of the first light-emitting layer and a material of the second light-emitting layer are different from each other.

22. The display device according to claim 18,
wherein, in a case where the ionization potential of the first light-emitting layer is smaller than the ionization potential of the second light-emitting layer,
the ionization potential of the first material is equal to or smaller than the ionization potential of the first light-emitting layer,
the ionization potential of the first light-emitting layer is smaller than the ionization potential of the second material, and
the ionization potential of the second material is equal to or smaller than the ionization potential of the second light-emitting layer.

23. The display device according to claim 18,
wherein the first material and the second material include nanoparticles.

24. The display device according to claim 18,
wherein the first material and the second material each include nanoparticles composed of Ni₁₋ₓMgₓO (0 ≤ x < 1), and
a composition (x) is different between the first material and the second material.

25. The display device according to claim 19,
wherein the first material, the second material, and the third material include nanoparticles, and
volume ratios of the first material, the second material, and the third material included in the hole transport layer become larger in descending order of magnitudes of the ionization potentials of the first material, the second material, and the third material.

26. The display device according to claim 19,
wherein the first material, the second material, and the third material include nanoparticles, and
at or near an interface with the anode electrode, volume ratios of the first material, the second material, and the third material included in the hole transport layer become larger in ascending order of magnitudes of the ionization potentials of the first material, the second material, and the third material.

27. The display device according to claim 19,
wherein the first material, the second material, and the third material include nanoparticles, and
at or near an interface with the first light-emitting layer, the second light-emitting layer, and the third light-emitting layer, volume ratios of the first material, the second material, and the third material included in the hole transport layer become larger in descending order of magnitudes of the ionization potentials of the first material, the second material, and the third material.

28. The display device according to claim 19,
wherein the first material, the second material, and the third material include nanoparticles, and
nanoparticles having the smallest ionization potential among the first material, the second material, and the third material decrease from a side of the anode electrode toward a side of the first, second, and third light-emitting layers.

29. The display device according to claim 28,
wherein nanoparticles other than the nanoparticles having the smallest ionization potential increase from the side of the anode electrode toward the side of the first, second, and third light-emitting layers.

30-33. (canceled)
